(19) United States
(12) Patent Application Publication
(10) Pub. No.: US 2025/0349731 A1
(43) Pub. Date: Nov. 13, 2025

(54) SEMICONDUCTOR PACKAGE AND MANUFACTURING METHOD THEREOF

(71) Applicant: Samsung Electronics Co., Ltd., Suwon-si (KR)

(72) Inventors: HYUNGJUN JEON, Suwon-si (KR); CHOONGBIN YIM, Suwon-si (KR)

(21) Appl. No.: 18/978,648

(22) Filed: Dec. 12, 2024

(30) Foreign Application Priority Data
May 10, 2024 (KR) 10-2024-0062101

(51) Int. Cl. H01L 23/538; H01L 23/00; H01L 23/14; H01L 23/15; H01L 23/31; H01L 23/373; H01L 23/48; H01L 25/16; H10B 80/00

(52) U.S. Cl. CPC H01L 23/5385; H01L 23/3135; H01L 24/08; H01L 25/16; H01L 23/145; H01L 23/15; H01L 23/3738; H01L 23/481; H10B 80/00

(57) ABSTRACT

A semiconductor package includes a first redistribution layer, a logic die on the first redistribution layer, a high bandwidth memory on the first redistribution layer and next to the logic die, a frame on the first redistribution layer, next to the logic die, and next to the high bandwidth memory, a molding material covering the logic die, the high bandwidth memory, and the frame, on the first redistribution layer, and a second redistribution layer on the molding material, where the second redistribution layer electrically connects the logic die to the high bandwidth memory.

### CROSS-REFERENCE TO RELATED APPLICATION

This application claims priority to and the benefit of Korean Patent Application No. 10-2024-0062101 filed in the Korean Intellectual Property Office on May 10, 2024, the entire contents of which are incorporated herein by reference.

### BACKGROUND OF THE INVENTION

### (a) Field of the Invention

The present disclosure relates to a semiconductor package and a manufacturing method thereof.

### (b) Description of the Related Art

A power management integrated circuit (PMIC) die is a device configured to supply electric power to semiconductor chips within a semiconductor package. The power management integrated circuit (PMIC) die may distribute a single supply power supplied from the outside of the semiconductor package differently depending on semiconductor chips, and may have a function to supply the distributed power to each of the semiconductor chips.

Such a power management integrated circuit (PMIC) die may be mounted on a board together with a 2.5D semiconductor package, and may be connected to the 2.5D semiconductor package through the board. In such a 2.5D semiconductor package structure, the electric power from the power management integrated circuit (PMIC) die is transferred to individual semiconductor chips through a path passing through a board, a substrate, an interposer, and the like, and due to the long path, the electric power from the power management integrated circuit (PMIC) die may decrease whenever passing through nodes, which may cause a problem of deteriorating the power transfer efficiency between the power management integrated circuit (PMIC) die and individual semiconductor chips.

Conventionally, in order to solve this problem, by embedding a metal-insulator-metal (MIM) capacitor or integrated stack capacitor (ISC) within the interposer, or embedding a capacitor within the substrate, the power characteristics were strengthened by compensating the decreased power.

However, when the interposer within which the metal-insulator-metal (MIM) capacitor or integrated stack capacitor (ISC) is embedded is used, the manufacturing cost of the semiconductor package may increase. In addition, in order to embed capacitors within the substrate, a multi-layer structure of more than 16 layers is required, and there are many design limitations for such an implementation. It may therefore be practically difficult to embed capacitors within the substrate.

Therefore, there is a need to develop a new semiconductor package technology that can solve these problems of the conventional semiconductor package technology.

### SUMMARY OF THE INVENTION

2.5D semiconductor package may be provided in which each of a logic die and a high bandwidth memory may be connected to a board by using a front-side redistribution layer (FRDL) structure formed of an organic dielectric, and a logic die and a high bandwidth memory may be interconnected by using a back-side redistribution layer (BRDL) structure formed of an inorganic dielectric.

The 2.5D semiconductor package may be provided in which a power management integrated circuit (PMIC) die is disposed on a lower surface of the front-side redistribution layer structure.

The 2.5D semiconductor package may be provided in which a lower surface of the logic die and the high bandwidth memory may be connected to the front-side redistribution layer structure, an upper surface of the logic die and the high bandwidth memory may be connected to a back-side redistribution layer structure, the logic die and high bandwidth memory may include the through-substrate vias, and the through-substrate vias may connect the front-side redistribution layer structure to a back-side redistribution layer structure.

The 2.5D semiconductor package may be provided in which an embedded trace substrate (ETS) may be disposed between the logic die and the memory die in a horizontal direction, and between the front-side redistribution layer structure and a back-side redistribution layer structure in a vertical direction.

In accordance with an aspect of the disclosure, a semiconductor package may include a first redistribution layer; a logic die on the first redistribution layer; a high bandwidth memory on the first redistribution layer and next to the logic die; a frame on the first redistribution layer, next to the logic die, and next to the high bandwidth memory; a molding material covering the logic die, the high bandwidth memory, and the frame, on the first redistribution layer; and a second redistribution layer on the molding material, wherein the second redistribution layer electrically connects the logic die to the high bandwidth memory.

In accordance with an aspect of the disclosure, a semiconductor package may include a first redistribution layer comprising a first surface and a second surface opposite to the first surface; a logic die on the first surface of the first redistribution layer; a high bandwidth memory on the first surface of the first redistribution layer and next to the logic die; a frame on the first surface of the first redistribution layer and between the logic die and the high bandwidth memory; a molding material covering the logic die, the high bandwidth memory, and the frame, on the first surface of the first redistribution layer; a second redistribution layer on the molding material, on the logic die, on the high bandwidth memory, and on the frame, wherein the second redistribution layer electrically connects the logic die to the high bandwidth memory; a heat sink on the second redistribution layer; and a power management integrated circuit (PMIC) die on the second surface of the first redistribution layer.

In accordance with an aspect of the disclosure, a manufacturing method of a semiconductor package may include forming a back-side redistribution layer on a carrier; bonding a logic die, a high bandwidth memory, and a frame on the back-side redistribution layer, wherein the back-side redistribution layer electrically connects the logic die to the high bandwidth memory; molding the logic die, the high bandwidth memory, and the frame with a molding material, on the back-side redistribution layer; and forming a front-side redistribution layer on the molding material, the logic die, the high bandwidth memory, and the frame.

The 2.5D semiconductor package may be provided in which a front-side redistribution layer structure formed of an organic dielectric and a back-side redistribution layer structure formed of an inorganic dielectric may be included, without using a substrate in which the capacitor is embedded, and without using an interposer in which a metal-insulator-metal (MIM) capacitor or an integrated stack capacitor (ISC) is embedded.

As such, without using a substrate in which a capacitor is embedded, the design of the 2.5D semiconductor package may be simplified, and the number of steps in the manufacturing process of the 2.5D semiconductor package may be reduced. In addition, as an interposer in which the expensive metal-insulator-metal (MIM) capacitor or the integrated stack the capacitor (ISC) is embedded may not be used, the manufacturing cost of the 2.5D semiconductor package may be reduced.

As a power management integrated circuit (PMIC) die disposed in the exterior of the conventional 2.5D semiconductor package is disposed on a lower surface of the front-side redistribution layer structure within the 2.5D semiconductor package, the length of the power transfer path may be reduced, and the power transfer efficiency may be prevented from decreasing.

The through-substrate vias may be disposed in each of the logic die and the high bandwidth memory, a lower surface of each of the logic die and the high bandwidth memory may be electrically connected to the front-side redistribution layer structure, an upper surface of each of the logic die and the high bandwidth memory may be electrically connected to a back-side redistribution layer structure, and accordingly, signals and electric power may be bi-directionally routed through the lower surface and the upper surface of each of the logic die and the high bandwidth memory, through which the 2.5D semiconductor package having a signal transmission path with improved signal characteristics and a power transfer path with improved power characteristics may be provided. The through-substrate vias may be, for example, through-silicon vias when the substrate is formed of silicon.

ETS may be disposed between the logic die and the memory die in the horizontal direction, and between the front-side redistribution layer structure and a back-side redistribution layer structure in the vertical direction, and the logic die and the memory die, and the front-side redistribution layer structure and the back-side redistribution layer structure may be electrically connected through the ETS. Accordingly, the size of the 2.5D semiconductor package may be reduced.

### BRIEF DESCRIPTION OF THE DRAWINGS

FIG. 1 is a cross-sectional view showing a semiconductor package of an embodiment.

FIG. 2 is a cross-sectional view showing a semiconductor package of another embodiment.

FIG. 3 is a cross-sectional view showing a semiconductor package of still another embodiment.

FIG. 4 is a cross-sectional view showing a semiconductor package of still another embodiment.

FIG. 5 to FIG. 16 are cross-sectional views showing a manufacturing method of semiconductor packages of FIG. 1, FIG. 2, FIG. 3, and FIG. 4.

### DETAILED DESCRIPTION OF THE EMBODIMENTS

Hereinafter, embodiments of the disclosure will be described in detail with reference to the accompanying drawings. The disclosure may be implemented in various forms, and may not necessarily limited to embodiments described herein.

The drawings and description are to be regarded as illustrative in nature and not restrictive. Like reference numerals designate like elements throughout the specification.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In contrast, when an element is referred to as being “directly connected” or “directly coupled” to another element, or as “contacting” or “in contact with” another element (or using any form of the word “contact”), there are no intervening elements present at the point of contact. In addition, unless explicitly described to the contrary, the words “comprise” and “include” and variations such as “comprises”, “comprising”, “includes”, or “including” will be understood to imply the inclusion of stated elements but not the exclusion of any other elements. Further, when a component is described as “including” a particular element or group of elements, it is to be understood that the component is formed of only the element or the group of elements, or the element or group of elements may be combined with additional elements to form the component, unless the context indicates otherwise.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

The various pads described herein may generally have a planar upper surface having horizontal dimensions (e.g., in both the X and Y directions) that are both larger than wiring to which the pad is connected to facilitate connections thereto (e.g., to provide a larger surface to contact a later formed via). For example, a horizontal wiring may be integrally formed with a pad (e.g., patterned out of the same metal layer) such that the wiring and pad have coplanar upper surfaces, with both of the X and Y horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have a symmetrical shape (e.g., a square or rectangular footprint) and may have X and Y horizontal dimensions that are about the same (e.g., within half to two times of the other).

Hereinafter, a semiconductor package 100 and manufacturing method of the semiconductor package 100 of an embodiment will be described in detail with reference to the drawings.

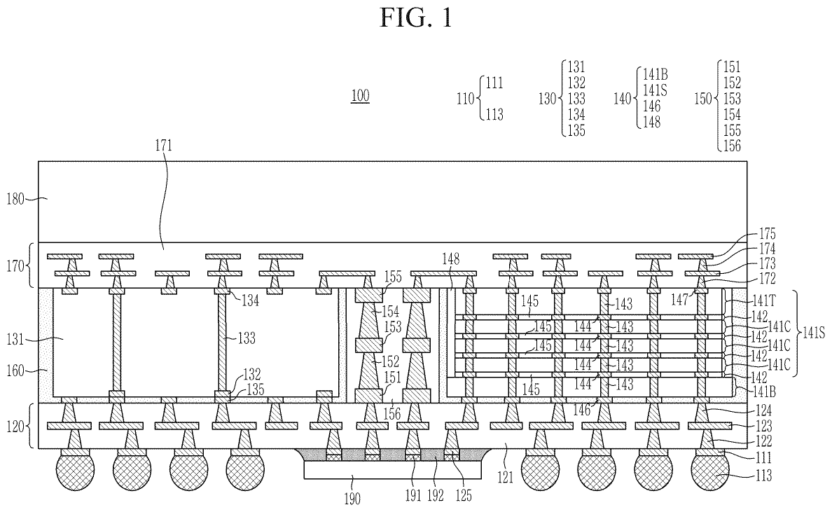

FIG. 1 is a cross-sectional view showing the semiconductor package 100 of an embodiment.

Referring to FIG. 1, the semiconductor package 100 may include an external connection structure 110, a front-side redistribution layer structure (e.g., a first redistribution layer structure, a front-side redistribution layer, or a first redistribution layer) 120, a logic die 130, a high bandwidth memory (HBM) 140, a substrate (e.g., a first connection structure, or a frame) 150, a molding material 160, a back-side redistribution layer structure (e.g., a second redistribution layer structure, a back-side redistribution layer, or a second redistribution layer) 170, a heat dissipation structure 180 (e.g., a heat sink), and a power management integrated circuit (PMIC) die 190. In an embodiment, the semiconductor package 100 may include a 2.5D semiconductor package. In an embodiment, the semiconductor package 100 may include a package-on-package (POP). In an embodiment, the semiconductor package 100 may be manufactured based on fan-out wafer level package (FOWLP) or fan-out panel level package (FOPLP) technology.

The external connection structure 110 may be disposed on a lower surface (e.g., a second surface) of a front-side redistribution layer structure 120. The external connection structure 110 may include first connection pads 111, and external connection members 113. Each of the first connection pads 111 may be disposed between a corresponding first redistribution via 122 of the front-side redistribution layer structure 120 and a corresponding external connection member 113. Each of the first connection pads 111 may electrically connect the corresponding first redistribution via 122 of the front-side redistribution layer structure 120 to the corresponding external connection member 113. The external connection member 113 may electrically connect the semiconductor package 100 to an external device (not shown).

The front-side redistribution layer structure 120 may include a first dielectric 121, first circuit wirings within the first dielectric 121, and bonding pads 125 on the first dielectric 121. The first circuit wirings may include the first redistribution vias 122, first redistribution lines 123, and second redistribution vias 124. In another embodiment, the front-side redistribution layer structure 120 including fewer or more redistribution lines, redistribution vias, and bonding pads may be included within the scope of the present disclosure. The front-side redistribution layer structure 120 may include a first surface and the second surface, which is an opposite surface of the first surface.

The first dielectric 121 may protect and insulate the first redistribution vias 122, the first redistribution lines 123, and the second redistribution vias 124. A first logic die 130, the high bandwidth memory (HBM) 140, and a substrate 150 may be disposed on an upper surface of the first dielectric 121. The external connection structure 110 and the power management integrated circuit (PMIC) die 190 may be disposed on a lower surface of the first dielectric 121. In an embodiment, the first dielectric 121 may include a photo imageable dielectric (PID) used in a redistribution layer process. The photo imageable dielectric (PID) may be a material capable of forming fine patterns by applying a photolithography process. As an embodiment, the photo imageable dielectric (PID) may include polyimide-based photoactive polymer, novolac-based photoactive polymer, polybenzoxazole, silicone-based polymer, acrylate-based polymer, or epoxy-based polymer.

Each of the first redistribution vias 122 may be disposed between corresponding first redistribution line 123 and the corresponding first connection pad 111, or between the corresponding first redistribution line 123 and the corresponding bonding pad 125. Each of the first redistribution vias 122 may electrically connect the corresponding first redistribution line 123 to the corresponding first connection pad 111, or the corresponding first redistribution line 123 to the corresponding bonding pad 125, in a vertical direction. Each of the first redistribution lines 123 may be disposed between the corresponding first redistribution via 122 and the corresponding second redistribution via 124. Each of the first redistribution lines 123 may electrically connect the corresponding first redistribution via 122 to the corresponding second redistribution via 124, in a horizontal direction. Each of the second redistribution vias 124 may be disposed between the corresponding first redistribution line 123 and a corresponding first connection terminal 135 of the logic die 130, between the corresponding first redistribution line 123 and a corresponding second connection terminal 146 of the high bandwidth memory (HBM) 140, or between the corresponding first redistribution line 123 and a corresponding first wire layer 151 of the substrate 150. Each of the second redistribution vias 124 may electrically connect the corresponding first connection terminal 135 of the logic die 130 to the corresponding first redistribution line 123, the corresponding second connection terminal 146 of the high bandwidth memory (HBM) 140 to the corresponding first redistribution line 123, or the corresponding first wire layer 151 of the substrate 150 to the corresponding first redistribution line 123. In an embodiment, the first redistribution via 122 and the second redistribution via 124 may have a width of an uppermost portion in the horizontal direction that is smaller than a width of a lowermost portion in the horizontal direction.

The logic die 130 may be disposed on the first surface of the front-side redistribution layer structure 120. The logic die 130 may be disposed next to the high bandwidth memory (HBM) 140. The logic die 130 may include a logic die base 131, lower connection pads 132, first through-substrate vias (TSV) 133, upper connection pads 134, and the first connection terminals 135. In an embodiment, the logic die 130 may include a system-on-chip (SoC). In an embodiment, the logic die 130 may include an application processor (AP). In an embodiment, the logic die 130 may include at least one of a central processing unit (CPU) and a graphics processing unit (GPU). The logic die 130 may be in contact with a back-side redistribution layer structure 170. The logic die 130 may be electrically connected to the back-side redistribution layer structure 170.

The lower connection pads 132 may be disposed within the logic die base 131. Each of the lower connection pads 132 may be disposed between a corresponding first through-substrate via (TSV) 133 and a corresponding first connection terminal 135, or between a corresponding internal wire (not shown) and the corresponding first connection terminal 135. Each of the lower connection pads 132 may electrically connect the corresponding first through-substrate via (TSV) 133 to the corresponding first connection terminal 135, or the corresponding internal wire (not shown) to the corresponding first connection terminal 135. In an embodiment, first lower connection pads 132 may include at least one of copper, aluminum, silver, tin, gold, nickel, lead, titanium, and an alloy thereof.

The first through-substrate vias (TSV) 133 may be disposed within the logic die base 131. Each of the first through-substrate vias (TSV) 133 may be disposed between the corresponding lower connection pad 132 and a corresponding upper connection pad 134. Each of the first through-substrate vias (TSV) 133 may electrically connect the corresponding upper connection pad 134 to the corresponding lower connection pad 132. According to the present disclosure, by disposing the first through-substrate vias (TSV) 133 within the logic die 130, the length of the electrical path between the front-side redistribution layer structure 120 and the back-side redistribution layer structure 170 may be reduced. In an embodiment, the first through-substrate vias (TSV) 133 may include at least one of tungsten, aluminum, copper, and an alloy thereof. As such, by disposing the first through-substrate vias (TSV) 133 within the logic die 130, signals and electric power may be directly transferred between the front-side redistribution layer structure 120 and the back-side redistribution layer structure 170.

The upper connection pads 134 may be disposed within the logic die base 131. Each of the upper connection pads 134 may be disposed between the corresponding first through-substrate via (TSV) 133 and a corresponding third redistribution via 172 of the back-side redistribution layer structure 170. Each of the upper connection pads 134 may electrically connect the corresponding third redistribution via 172 of the back-side redistribution layer structure 170 to the corresponding first through-substrate via (TSV) 133. In an embodiment, first upper connection pads 134 may include at least one of copper, aluminum, silver, tin, gold, nickel, lead, titanium, and an alloy thereof.

The first connection terminals 135 may be disposed on a lower surface of the logic die base 131. The first connection terminals 135 may be surrounded by the molding material 160. Each of the first connection terminals 135 may be disposed between a corresponding second redistribution via 124 of the front-side redistribution layer structure 120 and a corresponding lower connection pad 132 of the logic die 130. Each of the first connection terminals 135 may electrically connect the corresponding lower connection pad 132 of the logic die 130 to the corresponding second redistribution via 124 of the front-side redistribution layer structure 120. In an embodiment, the first connection terminals 135 may include at least one of copper, aluminum, silver, tin, gold, nickel, lead, titanium, and an alloy thereof.

The high bandwidth memory (HBM) 140 may be disposed on the first surface of the front-side redistribution layer structure 120. The high bandwidth memory (HBM) 140 may be disposed next to the logic die 130 in a horizontal direction. The high bandwidth memory (HBM) 140 may include a buffer die (base die; base logic die) 141B, a memory stack 141S including stacked memory dies (core dies) 141C and 141T, and interconnection structures 142 alternately disposed to the memory dies 141C and 141T, the second connection terminals 146, and a molding material 148. The high bandwidth memory (HBM) 140 according to the present disclosure is illustrated to include the memory stack 141S in which four memory dies 141C, 141T are stacked, but is not limited thereto, and may include the memory stack 141S in which various numbers of the memory dies 141C and 141T are stacked. For example, the high bandwidth memory (HBM) 140 may include the memory stack 141S in which eight, twelve, sixteen, or twenty-four memory dies or the like are stacked.

The high bandwidth memory (HBM) 140 may be a high performance three-dimensional (3D) stack dynamic random-access memory (DRAM). The high bandwidth memory (HBM) 140 may be manufactured in which one memory stack 141S is formed by vertically stacking the memory dies 141C and 141T including DRAM circuits, thousands of fine holes vertically penetrating the stacked memory dies 141C and 141T are formed in the memory dies 141C and 141T, and the technology of through-substrate via (TSV) 143 is used to fill a conductive material in the holes to electrically connect them.

The high bandwidth memory (HBM) 140 may provide the merits of

simultaneously implementing shorter latency and higher bandwidth compared to conventional DRAM products, by being provided with many memory channels through the memory stack 141S manufactured by vertically stacking the memory dies 141C and 141T, being advantageous in high bandwidth per unit area by reducing the total area on the substrate occupied by individual DRAMs, and reducing the power consumption.

The buffer die 141B may be disposed lowermost in the high bandwidth memory (HBM) 140, and may be disposed between the memory stack 141S and the front-side redistribution layer structure 120. When exchanging data between devices having different data processing speeds, processing units, and usage times, data loss may occur due to the difference in the data processing speed, the difference in processing unit, and the difference in usage time. In order to prevent such losses, the buffer die 141B may be disposed, such that information at the time of exchanging data between the memory stack 141S and the external device may be temporarily stored in the buffer die 141B. When transmitting data to the memory stack 141S, or receiving data from the memory stack 141S, the buffer die 141B may arrange data according to a sequence and then sequentially pass through data. The buffer die 141B may temporarily store data and may include an interface with latches, buffers and/or registers, and the like.

The buffer die 141B may include second through-substrate vias (TSV) 143. Each of the second through-substrate vias (TSV) 143 of the buffer die 141B may extend from a back end of line (BEOL) of the buffer die 141B to a back surface of the buffer die 141B. The second through-substrate vias (TSV) 143 of the buffer die 141B may be electrically connected to the memory stack 141S.

The memory stack 141S may be disposed on the buffer die 141B. The memory stack 141S may include the memory dies 141C and 141T and the interconnection structures 142. The memory dies 141C and 141T may be stacked by alternating with the interconnection structures 142. In an embodiment, the memory dies 141C and 141T may be a DRAM. An uppermost memory die 141T may be in contact with the back-side redistribution layer structure 170. The uppermost memory die 141T may be electrically connected to the back-side redistribution layer structure 170.

The memory dies 141C and 141T may include the second through-substrate vias (TSV) 143. The second through-substrate vias (TSV) 143 may extend from a back end of line (BEOL) of each of the memory dies 141C and 141T to a back surface of each of the memory dies 141C and 141T. Each of the second through-substrate vias (TSV) 143 of the memory dies 141C may be connected to each of the memory dies 141C and 141T above them. The second through-substrate vias (TSV) 143 of the uppermost memory die 141T may be electrically connected to the back-side redistribution layer structure 170 through the connection pads 147. According to the present disclosure, as the second through-substrate vias (TSV) 143 are disposed within the uppermost memory die 141T of the high bandwidth memory (HBM) 140, the signals and electric power from the high bandwidth memory (HBM) 140 and to the high bandwidth memory (HBM) 140 may be routed toward an upper surface (e.g., toward the back-side redistribution layer structure 170), and toward a lower surface (e.g., toward the front-side redistribution layer structure 120) of the high bandwidth memory (HBM) 140.

The second through-substrate vias (TSV) 143 of the buffer die 141B and the memory dies 141C and 141T may reduce the length of the signal and power transfer path in the vertical direction, and thereby may serve to improve signal characteristics and power characteristics. In an embodiment, the second through-substrate vias (TSV) 143 may include at least one of tungsten, aluminum, copper, and an alloy thereof.

The interconnection structures 142 may be disposed between the buffer die 141B and the memory stack 141S, and between the memory dies 141C and 141T neighboring to each other. An interconnection structure 142 may include conductive members 144 and an insulation member 145. In an embodiment, the conductive members 144 may include the bonding pads on which metal-metal hybrid bonding is performed, and the insulation member 145 may include a silicon insulator on which non-metal-non-metal hybrid bonding is performed. In an embodiment, the conductive members 144 may include micro-bumps on which flip chip bonding is performed, and the insulation member 145 may include a non-conductive film (NCF) configured to protect and insulate the conductive members 144.

The second connection terminals 146 may be disposed between the buffer die 141B and the front-side redistribution layer structure 120. The second connection terminals 146 may electrically connect the buffer die 141B to the front-side redistribution layer structure 120. The second connection terminals 146 may be surrounded by the molding material 160. In an embodiment, the second connection terminals 146 may include at least one of copper, aluminum, silver, tin, gold, nickel, lead, titanium, and an alloy thereof.

The molding material 148 may be disposed on the buffer die 141B, and may cover the memory stack 141S. In an embodiment, the molding material 148 may include an epoxy molding compound (EMC).

The substrate 150 may be disposed on the first surface of the front-side redistribution layer structure 120. The substrate 150 may be disposed between the front-side redistribution layer structure 120 and the back-side redistribution layer structure 170. The substrate 150 may electrically connect the back-side redistribution layer structure 170 to the front-side redistribution layer structure 120. The substrate 150 may be disposed between the logic die 130 and the high bandwidth memory (HBM) 140. As such, by disposing the substrate 150 between the logic die 130 and the high bandwidth memory (HBM) 140 in the horizontal direction, and between the front-side redistribution layer structure 120 and the back-side redistribution layer structure 170 in the vertical direction, the logic die 130 and the high bandwidth memory (HBM) 140 may be electrically connected in the horizontal direction, and the front-side redistribution layer structure 120 and the back-side redistribution layer structure 170 may be electrically connected in the vertical direction, and accordingly, the size of the semiconductor package 100 may be reduced. The electric power from the power management integrated circuit (PMIC) die 190 may be supplied to the logic die 130 and the high bandwidth memory (HBM) 140 through the substrate 150. The substrate 150 may include the first wire layer 151, a first via 152, a second wire layer 153, a second via 154, a third wire layer 155, and an insulation layer 156. In an embodiment, the substrate 150 may include an embedded trace substrate (ETS).

Each of the first wire layers 151 may be disposed between a corresponding second redistribution via 124 of the front-side redistribution layer structure 120 and a corresponding first via 152. Each of the first wire layers 151 may electrically connect the corresponding first via 152 to the corresponding second redistribution via 124 of the front-side redistribution layer structure 120 in the horizontal direction. Each of the first vias 152 may be disposed between the corresponding first wire layer 151 and the corresponding second wire layer 153. Each of the first vias 152 may electrically connect the corresponding second wire layer 153 to the corresponding first wire layer 151 in the vertical direction. Each of the second wire layers 153 may be disposed between a corresponding first via 152 and a corresponding second via 154. Each of the second wire layers 153 may electrically connect the corresponding second via 154 to the corresponding first via 152 in the horizontal direction. Each of the second vias 154 may be disposed between a corresponding second wire layer 153 and a corresponding third wire layer 155. Each of the second vias 154 may electrically connect the corresponding third wire layer 155 to the corresponding second wire layer 153 in the vertical direction. Each of the third wire layers 155 may be disposed between a corresponding second via 154 and a corresponding third redistribution via 172 of the back-side redistribution layer structure 170. Each of the third wire layers 155 may electrically connect the corresponding third redistribution via 172 of the back-side redistribution layer structure 170 to the corresponding second via 154 in the horizontal direction.

The insulation layer 156 may surround and protect the first wire layers 151, the first vias 152, the second wire layers 153, the second vias 154, and the third wire layers 155. In the embodiment of FIG. 1, the substrate 150 includes two layers of vias, but in another embodiment, the substrate 150 may have multiple layers including three or more layers of vias. In another embodiment, the substrate 150 including fewer or more wire layers and vias may be included within the scope of the present disclosure. In an embodiment, the insulation layer 156 may include a thermosetting resin such as an epoxy resin, a thermoplastic resin such as polyimide, or a material in which the above-mentioned resin is mixed with an inorganic filler. In an embodiment, the insulation layer 156 may include a resin impregnated into a core material of glass fiber, glass fabric or glass cloth or the like together with an inorganic filler. In an embodiment, the insulation layer 156 may include prepreg, Ajinomoto Build-up Film (ABF), FR-4, or bismaleimide triazine (BT). In an embodiment, the insulation layer 156 may include a photo imageable dielectric (PID). In an embodiment, each of the first wire layer 151, the second wire layer 153, and the third wire layer 155 may include at least one of copper, aluminum, silver, tin, gold, nickel, lead, titanium, and an alloy thereof. In an embodiment, each of the first vias 152 and the second vias 154 may include at least one of copper, aluminum, silver, tin, gold, nickel, lead, titanium, and an alloy thereof.

The molding material 160 may be disposed on the first surface of the front-side redistribution layer structure 120, and may cover the logic die 130, the high bandwidth memory (HBM) 140, and the substrate 150.

The back-side redistribution layer structure 170 may be disposed on the logic die 130, on the high bandwidth memory (HBM) 140, on the substrate 150, and on the molding material 160. The back-side redistribution layer structure 170 may include a second dielectric 171 and second circuit wirings within the second dielectric 171. The second circuit wirings may include the third redistribution vias 172, second redistribution lines 173, and fourth redistribution vias 174. In another embodiment, the back-side redistribution layer structure 170 including fewer or more redistribution lines and redistribution vias may be included within the scope of the present disclosure.

The second dielectric 171 may protect and insulate the third redistribution vias 172, the second redistribution lines 173, and the fourth redistribution vias 174. The heat dissipation structure 180 may be disposed on an upper surface of the second dielectric 171. The logic die 130, the high bandwidth memory (HBM) 140, the substrate 150, and the molding material 160 may be disposed on a lower surface of the second dielectric 171. Respective upper surfaces of the logic die 130, the high bandwidth memory (HBM) 140, the substrate 150, and the molding material 160 may have the same vertical level, and may be in contact with the second dielectric 171.

The second dielectric 171 may include a material having the coefficient of thermal expansion (CTE) similar to that of the main material of the logic die 130 and the high bandwidth memory (HBM) 140. The second dielectric 171 may include a material having the thermal conductivity similar to that of the main material of the logic die 130 and the high bandwidth memory (HBM) 140. In an embodiment, the second dielectric 171 may include silicon oxide, silicon nitride, silicon oxynitride, TEOS formation oxide, phosphosilicate glass (PSG), borophosphosilicate glass (BPSG), a low-k dielectric material, other appropriate dielectric materials, or a combination thereof.

As an exemplary material of the photo imageable dielectric (PID), the coefficient of thermal expansion (CTE) of polyimide may be about 40-80×10×6/° C., and the coefficient of thermal expansion (CTE) of the epoxy resin may be about 50-80×10×6/° C. As an exemplary material of the second dielectric 171, the logic die 130, and the high bandwidth memory (HBM) 140, the coefficient of thermal expansion (CTE) of silicon oxide SiO2 may be about 0.55×10−6/° C. According to the present disclosure, by forming the back-side redistribution layer structure 170 with the second dielectric 171 having the coefficient of thermal expansion (CTE) similar to the coefficient of thermal expansion (CTE) of the main material of the logic die 130 and the high bandwidth memory (HBM) 140, warpage of the semiconductor package 100 may be decreased compared to the case of forming the back-side redistribution layer structure 170 with the photo imageable dielectric (PID).

As an exemplary material of the photo imageable dielectric (PID), the thermal conductivity of polyimide may be about 0.28 to 0.34 W/mK, and the thermal conductivity of epoxy resin may be about 0.3 W/mK. As an exemplary material of the second dielectric 171, the thermal conductivity of silicon may be about 83.7 W/mK. The thermal conductivity of the second dielectric 171 is greater than the thermal conductivity of the photo imageable dielectric (PID) of the front-side redistribution layer structure 120. According to the present disclosure, by forming the back-side redistribution layer structure 170 with the second dielectric 171, compared to the case of forming the back-side redistribution layer structure 170 with the photo imageable dielectric (PID), the heat generated from the logic die 130 and the high bandwidth memory (HBM) 140 may be efficiently dissipated, and the thermal property of the semiconductor package 100 may be improved.

Each of the third redistribution vias 172 may be disposed between a corresponding second redistribution line 173 and a corresponding upper connection pad 134 of the logic die 130, between a corresponding second redistribution line 173 and a corresponding connection pad 147 of the high bandwidth memory (HBM) 140, or between a corresponding second redistribution line 173 and the third wire layer 155 of the substrate 150. Each of the third redistribution vias 172 may electrically connect the corresponding second redistribution line 173 to the corresponding upper connection pad 134 of the logic die 130, the corresponding second redistribution line 173 to the corresponding connection pad 147 of the high bandwidth memory (HBM) 140, or the corresponding second redistribution line 173 to the third wire layer 155 of the substrate 150. Each of the second redistribution lines 173 may be disposed between a corresponding third redistribution via 172 and a corresponding fourth redistribution via 174. Each of the second redistribution lines 173 may electrically connect the corresponding fourth redistribution via 174 to the corresponding third redistribution via 172 in the horizontal direction, the third redistribution via 172 connected to the upper connection pad 134 of the logic die 130 to the third redistribution via 172 connected to the third wire layer 155 of the substrate 150, or the third redistribution via 172 connected to the connection pad 147 of the high bandwidth memory (HBM) 140 to the third redistribution via 172 connected to the third wire layer 155 of the substrate 150. Each of the fourth redistribution vias 174 may be disposed between a corresponding second redistribution line 173 and a corresponding third redistribution line 175. Each of the fourth redistribution vias 174 may electrically connect the corresponding third redistribution line 175 to the corresponding second redistribution line 173. Each of the third redistribution lines 175 may be disposed on the corresponding fourth redistribution via 174. Each of the third redistribution lines 175 may be electrically connected to the corresponding fourth redistribution vias 174. In an embodiment, the third redistribution via 172 and the fourth redistribution via 174 may have a width of an uppermost portion in the horizontal direction that is smaller than a width of a lowermost portion in the horizontal direction.

The heat dissipation structure 180 may be disposed on the back-side redistribution layer structure 170. The heat dissipation structure 180 may contact the second dielectric 171 of the back-side redistribution layer structure 170 without the connection members. The heat dissipation structure 180 may be electrically separated (e.g., isolated) from other elements. In an embodiment, the heat dissipation structure 180 may be formed of a conductive material or metal material having a high thermal conductivity. In an embodiment, the heat dissipation structure 180 may include copper, aluminum, gold, silver, steel, or stainless steel (SUS). In an embodiment, the heat dissipation structure 180 may be formed of a silicon material. In an embodiment, the heat dissipation structure 180 may be a carrier used in the manufacturing process. As such, by disposing the heat dissipation structure 180 on the back-side redistribution layer structure 170, the heat generated within the logic die 130 and the high bandwidth memory (HBM) 140 may be dissipated to the outside through the back-side redistribution layer structure 170 and the heat dissipation structure 180. Accordingly, the thermal property of the semiconductor package 100 may be improved.

The power management integrated circuit (PMIC) die 190 may be disposed on the lower surface (e.g., the second surface) of the front-side redistribution layer structure 120. The power management integrated circuit (PMIC) die 190 may be disposed between the external connection members 113. For example, the power management integrated circuit (PMIC) die 190 may be at least partially surrounded by the external connection members 113 on the lower surface of the front-side redistribution layer structure 120. The power management integrated circuit (PMIC) die 190 may distribute a single supply power supplied from the outside of the semiconductor package 100 differently depending on the logic die 130 and the high bandwidth memory (HBM) 140, and may have a function to supply the distributed power to each of the logic die 130 and the high bandwidth memory (HBM) 140. In an embodiment, the power management integrated circuit (PMIC) die 190 may include at least one of a controller, a buck converter, a capacitor, a resistor, and an inductor. In an embodiment, the power management integrated circuit (PMIC) die 190 may include a regulator.

Each of the connection members 191 may be disposed between the power management integrated circuit (PMIC) die 190 and each of the bonding pads 125 of the front-side redistribution layer structure 120. Each of the connection members 191 may electrically connect the power management integrated circuit (PMIC) die 190 to a corresponding bonding pad 125 of the front-side redistribution layer structure 120. In an embodiment, the connection member 191 may include a micro-bump or solder ball. In an embodiment, the connection member 191 may include at least one of tin, silver, lead, nickel, copper, and an alloy thereof.

An insulation member 192 may be disposed between the power management integrated circuit (PMIC) die 190 and the first dielectric 121 of the front-side redistribution layer structure 120. The insulation member 192 may surround and protect the bonding pads 125 and the connection members 191. In an embodiment, the insulation member 192 may include a capillary underfill (CUF), a non-conductive film (NCF), or a non-conductive paste (NCP). A first surface of the insulation member 192 may be in contact with the first dielectric 121 and a second surface (opposite to the first surface) of the insulation member 192 may be in contact with the power management integrated circuit (PMIC) die 190.

In a conventional arrangement, a power management integrated circuit (PMIC) die 190 is disposed outside of a conventional semiconductor package. In contrast, according to the present disclosure, the power management integrated circuit (PMIC) die 190 may be disposed on a lower surface of the front-side redistribution layer structure 120. Accordingly, through the power management integrated circuit (PMIC) die 190, the front-side redistribution layer structure 120, the substrate 150, and the back-side redistribution layer structure 170, a routing path to transfer the electric power to the logic die 130 and the high bandwidth memory (HBM) 140 may be formed, such that the length of the power transfer path may be shortened, and the power transfer efficiency may be prevented from decreasing.

According to the present disclosure, through-substrate vias may be disposed in each of the logic die 130 and the high bandwidth memory (HBM) 140, and the substrate 150 may be disposed between the logic die 130 and the high bandwidth memory (HBM) 140, such that the routing path of the signals and electric power in the vertical direction may be designed. In addition, a lower surface of each of the logic die 130 and the high bandwidth memory (HBM) 140 may be electrically connected to the front-side redistribution layer structure 120, and an upper surface of each of the logic die 130 and the high bandwidth memory (HBM) 140 may be electrically connected to the back-side redistribution layer structure 170, such that, through the lower surface and the upper surface of each of the logic die 130 and the high bandwidth memory (HBM) 140, a routing path of the signals and electric power in the horizontal direction may be bi-directionally designed. Through such a design, a signal transmission path with improved signal characteristics and a power transfer path with improved power characteristics may be implemented, and the size of the semiconductor package 100 may be reduced.

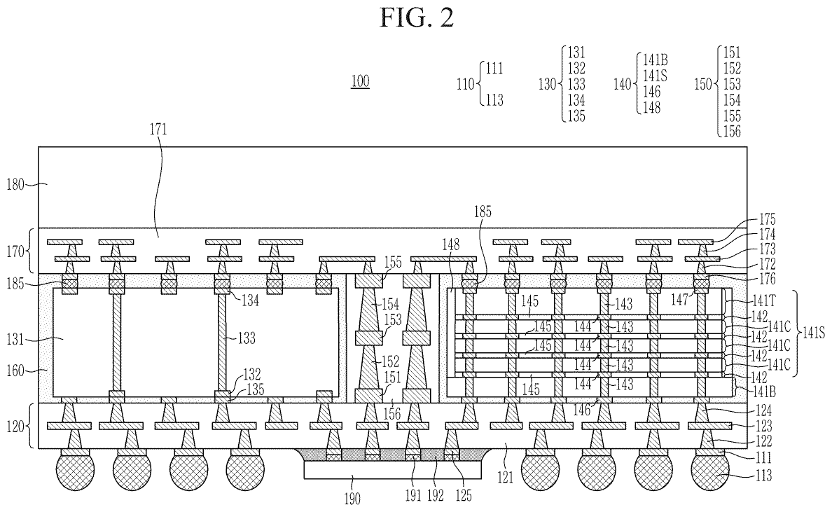

FIG. 2 is a cross-sectional view showing the semiconductor package 100 of another embodiment.

Referring to FIG. 2, the semiconductor package 100 may include the connection members 185. The back-side redistribution layer structure 170 may include the bonding pads 176 on its lower surface. Each of the connection members 185 may be disposed between a corresponding upper connection pad 134 of the logic die 130 and a corresponding bonding pad 176, or between a corresponding connection pad 147 of the high bandwidth memory (HBM) 140 and a corresponding bonding pad 176. Each of the connection members 185 may electrically connect the corresponding bonding pad 176 to the corresponding upper connection pad 134 of the logic die 130, or the corresponding bonding pad 176 to the corresponding connection pad 147 of the high bandwidth memory (HBM) 140. Each of the bonding pads 176 may be disposed between the corresponding connection member 185 and a corresponding third redistribution via 172 of the back-side redistribution layer structure 170. Each of the bonding pads 176 may electrically connect the corresponding third redistribution via 172 of the back-side redistribution layer structure 170 to the corresponding connection member 185. In an embodiment, the connection members 185 and the bonding pads 176 may be surrounded by Molded Underfill (MUF). In an embodiment, the connection members 185 and the bonding pads 176 may be surrounded by capillary underfill (CUF), a non-conductive film (NCF), or a non-conductive paste (NCP). In an embodiment, the connection members 185 may include at least one of tin, silver, lead, nickel, copper, and an alloy thereof. In an embodiment, the connection member 185 may include a micro-bump or solder ball. In an embodiment, the bonding pads 176 may include at least one of copper, aluminum, silver, tin, gold, nickel, lead, titanium, and an alloy thereof.

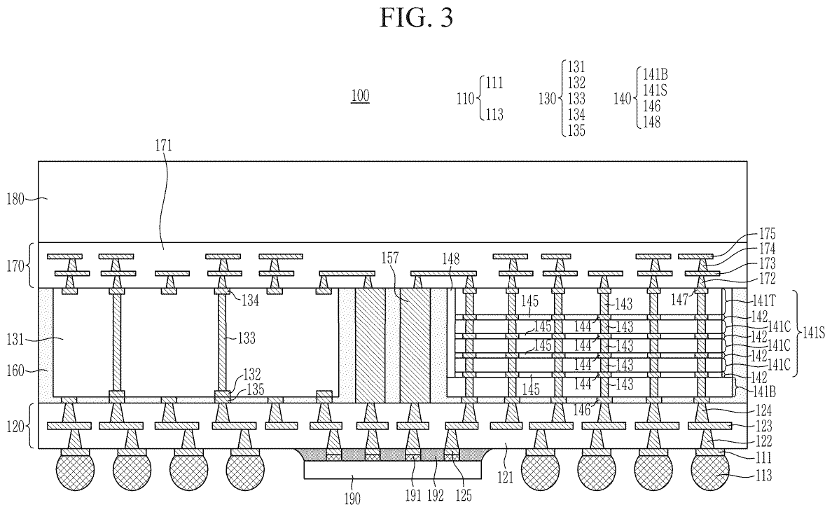

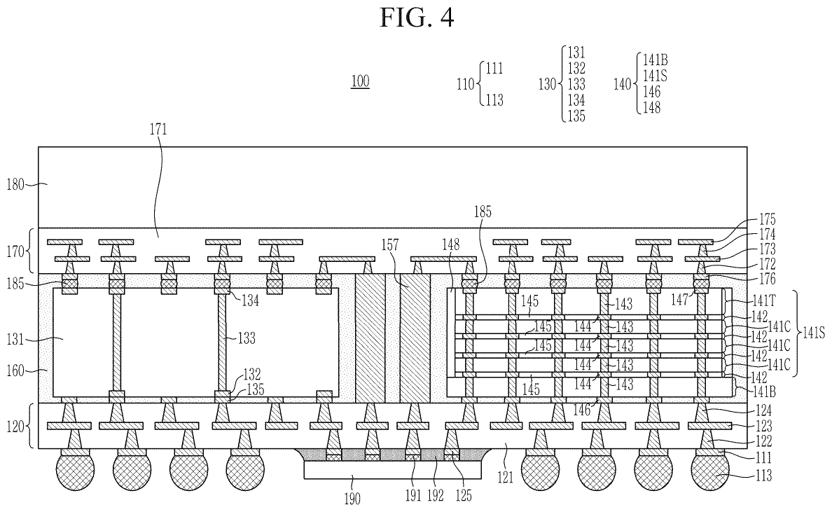

FIG. 3 and FIG. 4 are cross-sectional views showing the semiconductor packages 100 of still another embodiment. FIG. 3 illustrates an embodiment in which the substrate 150 in the configuration of the semiconductor package 100 of FIG. 1 is replaced with conductive posts 157. FIG. 4 illustrates an embodiment in which the substrate 150 in the configuration of the semiconductor package 100 of FIG. 2 is replaced with the conductive posts 157. Referring to FIG. 3 FIG. 4, the semiconductor package 100 may include the conductive posts (second connection structure) 157. The conductive posts 157 may be disposed on the front-side redistribution layer structure 120. The conductive posts 157 may be disposed between the front-side redistribution layer structure 120 and the back-side redistribution layer structure 170. The conductive posts 157 may electrically connect the back-side redistribution layer structure 170 to the front-side redistribution layer structure 120. Each of the conductive posts 157 may be disposed between a corresponding second redistribution via 124 of the front-side redistribution layer structure 120 and a corresponding third redistribution via 172 of the back-side redistribution layer structure 170. Each of the conductive posts 157 may electrically connect the corresponding third redistribution via 172 of the back-side redistribution layer structure 170 to the corresponding second redistribution via 124 of the front-side redistribution layer structure 120. The conductive posts 157 may be disposed between the logic die 130 and the high bandwidth memory (HBM) 140 in the horizontal direction. As such, by disposing the conductive posts 157 between the logic die 130 and the high bandwidth memory (HBM) 140 in the horizontal direction and between the front-side redistribution layer structure 120 and the back-side redistribution layer structure 170 in the vertical direction, the logic die 130 and the high bandwidth memory (HBM) 140 may be electrically connected in the horizontal direction, and the front-side redistribution layer structure 120 and the back-side redistribution layer structure 170 may be electrically connected in the vertical direction, and accordingly, the size of the semiconductor package 100 may be reduced. The electric power from the power management integrated circuit (PMIC) die 190 may be supplied to the logic die 130 and the high bandwidth memory (HBM) 140 through the conductive posts 157.

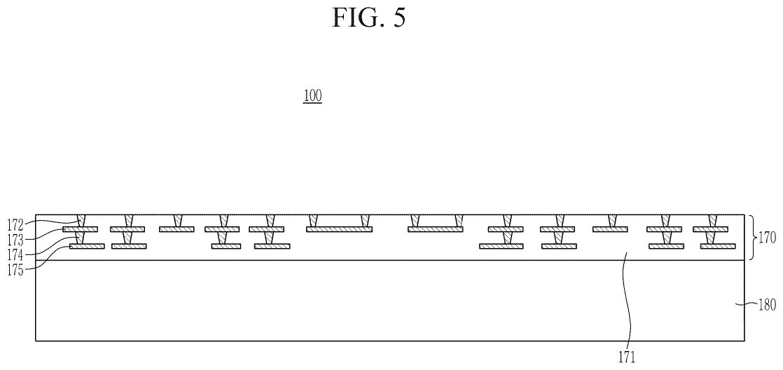

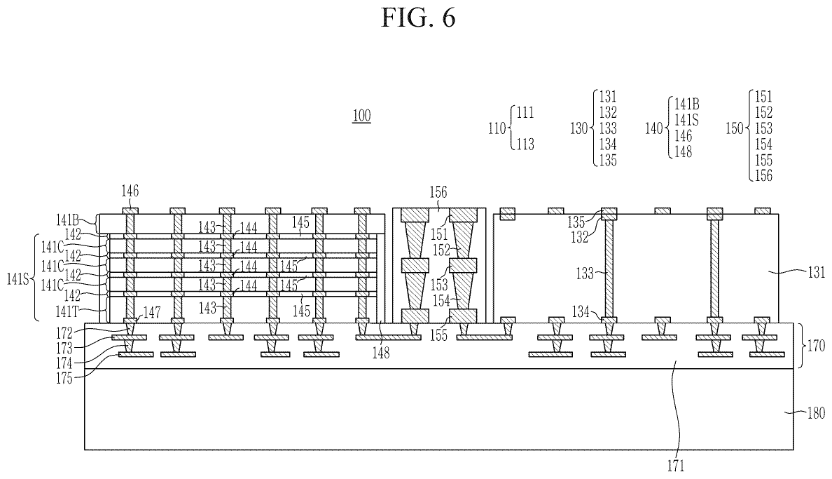

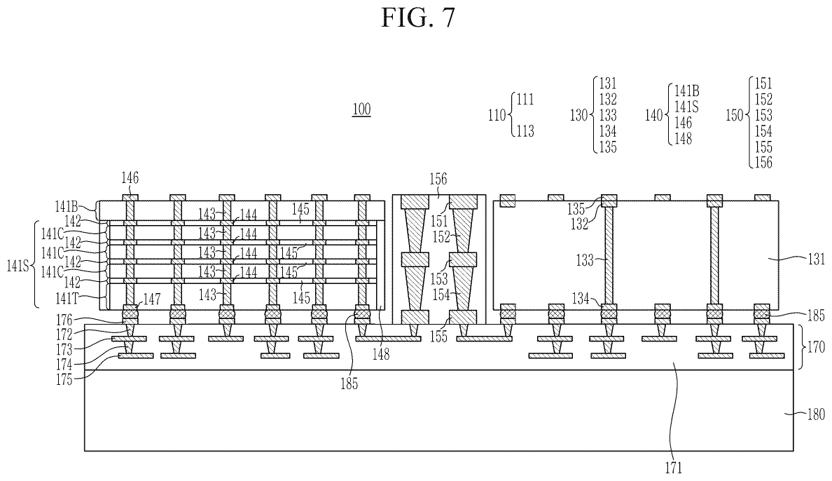

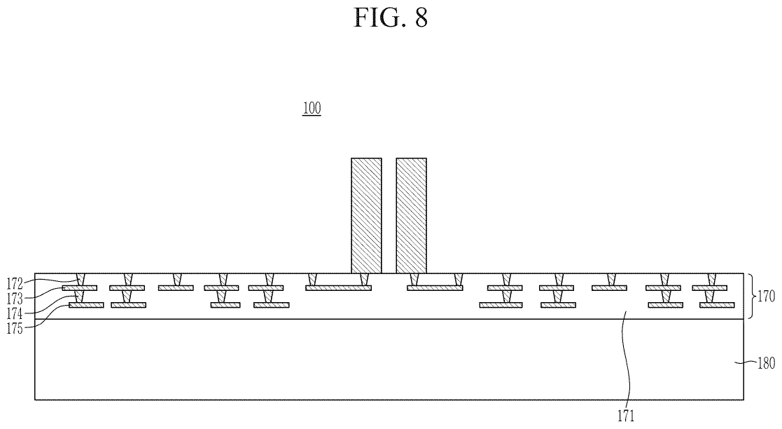

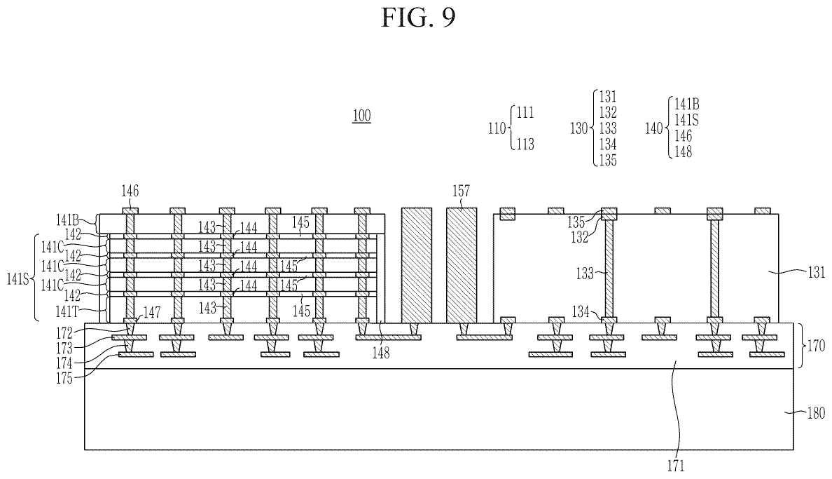

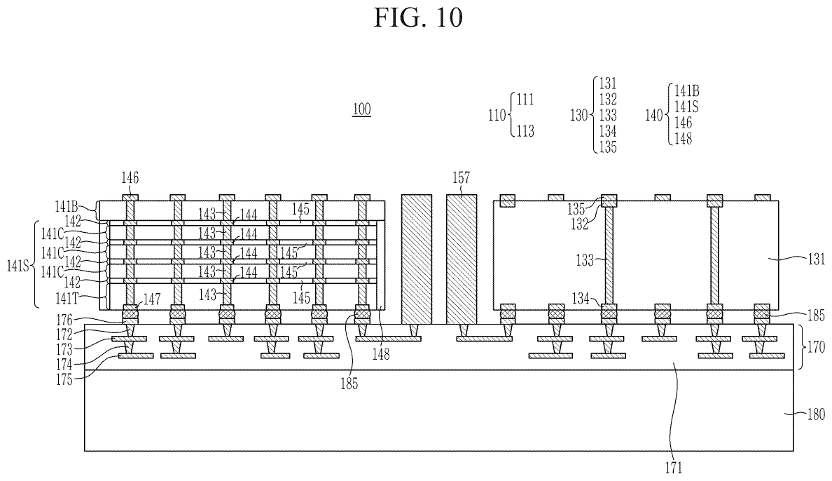

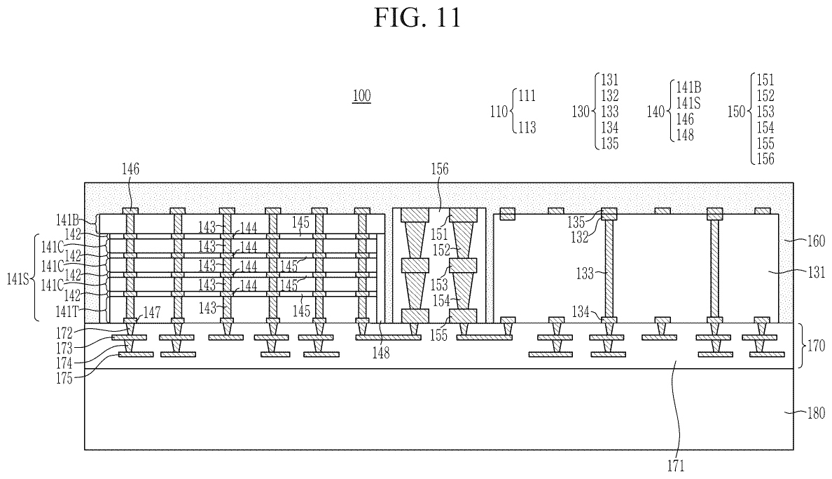

FIG. 5 to FIG. 16 are cross-sectional views showing a manufacturing method of the semiconductor packages 100 of FIG. 1, FIG. 2, FIG. 3, and FIG. 4. FIG. 5, FIG. 6, and FIG. 11 to FIG. 16 are cross-sectional views showing a manufacturing method of the semiconductor package 100 of FIG. 1. FIG. 5 and FIG. 7 are cross-sectional views showing a manufacturing method of the semiconductor package 100 of FIG. 2. A manufacturing method of the semiconductor package 100 of FIG. 1 according to FIG. 11 to FIG. 16 may be applied to a manufacturing method of the semiconductor package 100 of FIG. 2, subsequently to FIG. 5 and FIG. 7. FIG. 5, FIG. 8 and FIG. 9 are cross-sectional views showing a manufacturing method of the semiconductor package 100 of FIG. 3. A manufacturing method of the semiconductor package 100 of FIG. 1 according to FIG. 11 to FIG. 16 may be applied to a manufacturing method of the semiconductor package 100 of FIG. 3, subsequently to FIG. 5, FIG. 8 and FIG. 9. FIG. 5, FIG. 8 and FIG. 10 are cross-sectional views showing a manufacturing method of the semiconductor package 100 of FIG. 4. A manufacturing method of the semiconductor package 100 of FIG. 1 according to FIG. 11 to FIG. 16 may be applied to a manufacturing method of the semiconductor package 100 of FIG. 4, subsequently to FIG. 5, FIG. 8 and FIG. 10.

FIG. 5 is a cross-sectional view showing the step of forming the back-side redistribution layer structure 170 on the carrier (e.g., the heat dissipation structure) 180.

Referring to FIG. 5, the back-side redistribution layer structure 170 on a carrier 180 may be formed. First, the carrier 180 may be provided. In an embodiment, the carrier 180 may include a material acting as the heat dissipation structure.

Then, the second dielectric 171 on the carrier 180 may be formed. In an embodiment, the second dielectric 171 may be formed of an inorganic dielectric material. In an embodiment, the second dielectric 171 may be formed by performing a process of chemical vapor deposition (CVD), atomic layer deposition (ALD), or plasma enhanced chemical vapor deposition (PECVD).

After forming the second dielectric 171, the second dielectric 171 may be selectively etched to form openings, and the third redistribution lines 175 may be formed by filling a conducting material in the openings. After forming the third redistribution lines 175, the second dielectric 171 may be additionally deposited on the third redistribution lines 175 and the second dielectric 171, the additionally deposited second dielectric 171 may be selectively etched to form via holes, and the fourth redistribution vias 174 may be formed by filling a conducting material in the via holes. After forming the fourth redistribution vias 174, the second dielectric 171 may be additionally deposited on the fourth redistribution vias 174 and the second dielectric 171, the additionally deposited second dielectric 171 may be selectively etched to form openings, and the second redistribution lines 173 may be formed by filling a conducting material in the openings. After forming the second redistribution lines 173, the second dielectric 171 may be additionally deposited on the second redistribution lines 173 and the second dielectric 171, the additionally deposited second dielectric 171 may be selectively etched to form via holes, and the third redistribution vias 172 may be formed by filling a conducting material in the via holes.

Based on the final semiconductor package 100, since the back-side redistribution layer structure 170 is manufactured upside down, a width of an uppermost portion of each of the third redistribution vias 172 in the final product may be smaller than a width of the lowermost portion, and a width of an uppermost portion of each of the fourth redistribution vias 174 may be smaller than the width of the lowermost portion.

In an embodiment, each of the third redistribution vias 172, the second redistribution lines 173, the fourth redistribution vias 174, and the third redistribution lines 175 may include at least one of copper, aluminum, tungsten, nickel, gold, tin, titanium, and an alloy thereof. In an embodiment, each of the third redistribution vias 172, the second redistribution lines 173, the fourth redistribution vias 174, and the third redistribution lines 175 may be formed by performing a sputtering process. In another embodiment, each of the third redistribution vias 172, the second redistribution lines 173, the fourth redistribution vias 174, and the third redistribution lines 175 may be formed by performing an electroplating process after forming a seed metal layer.

FIG. 6 is a cross-sectional view showing the step of bonding the logic die 130, the high bandwidth memory (HBM) 140, and the substrate 150 on the back-side redistribution layer structure 170.

Referring to FIG. 6, the logic die 130, the high bandwidth memory (HBM) 140, and the substrate 150 are bonded on the back-side redistribution layer structure 170. In an embodiment, the logic die 130, the high bandwidth memory (HBM) 140, and the substrate 150 may be bonded on the back-side redistribution layer structure 170 by performing a thermal compression (TC) process. The logic die 130, the high bandwidth memory (HBM) 140, and the substrate 150 may be disposed side by side and at the same vertical level. The logic die 130, the high bandwidth memory (HBM) 140, and the substrate 150 may be directly bonded to the back-side redistribution layer structure 170, and thereby electrically connected thereto.

FIG. 7 is a cross-sectional view showing the step of bonding the logic die 130, the high bandwidth memory (HBM) 140, and the substrate 150 on the back-side redistribution layer structure 170, subsequently to FIG. 5.

Referring to FIG. 7, the logic die 130, the high bandwidth memory (HBM) 140, and the substrate 150 may be bonded on the back-side redistribution layer structure 170. In an embodiment, the logic die 130 and the high bandwidth memory (HBM) 140 may be bonded on the back-side redistribution layer structure 170 by performing a flip chip bonding process. In an embodiment, the substrate 150 may be bonded on the back-side redistribution layer structure 170 by performing a thermal compression (TC) process. The logic die 130, the high bandwidth memory (HBM) 140, and the substrate 150 may be disposed side by side and at the same level. The logic die 130 and the high bandwidth memory (HBM) 140 may be bonded to the back-side redistribution layer structure 170 by the connection members 185, and thereby electrically connected thereto. The substrate 150 may be directly bonded to the back-side redistribution layer structure 170, and thereby electrically connected thereto.

FIG. 8 is a cross-sectional view showing the step of forming the conductive posts 157 on the back-side redistribution layer structure 170, subsequently to FIG. 5.

Referring to FIG. 8, the conductive posts 157 on the back-side redistribution layer structure 170 may be formed. In an embodiment, the conductive posts 157 may be formed by performing a sputtering process. In another embodiment, the conductive posts 157 may be formed by performing an electroplating process after forming a seed metal layer. In an embodiment, the conductive posts 157 may include at least one of copper, aluminum, tungsten, nickel, gold, silver, chromium, antimony, tin, titanium, and an alloy thereof.

FIG. 9 is a cross-sectional view showing the step of bonding the logic die 130 and the high bandwidth memory (HBM) 140 on the back-side redistribution layer structure 170, subsequently to FIG. 8.

Referring to FIG. 9, the logic die 130 and the high bandwidth memory (HBM) 140 may be bonded on the back-side redistribution layer structure 170. In an embodiment, the logic die 130 and the high bandwidth memory (HBM) 140 may be bonded on the back-side redistribution layer structure 170 by performing a thermal compression (TC) process. The logic die 130, the high bandwidth memory (HBM) 140, and the conductive posts 157 may be disposed side by side and at the same vertical level. The logic die 130 and the high bandwidth memory (HBM) 140 may be directly bonded to the back-side redistribution layer structure 170, and thereby electrically connected thereto.

FIG. 10 is a cross-sectional view showing the step of bonding the logic die 130 and the high bandwidth memory (HBM) 140 on the back-side redistribution layer structure 170, subsequently to FIG. 8.

Referring to FIG. 10, the logic die 130 and the high bandwidth memory (HBM) 140 may be bonded on the back-side redistribution layer structure 170. In an embodiment, the logic die 130 and the high bandwidth memory (HBM) 140 may be bonded on the back-side redistribution layer structure 170 by performing a flip chip bonding process. The logic die 130, the high bandwidth memory (HBM) 140, and the conductive posts 157 may be disposed side by side and at the same vertical level. The logic die 130 and the high bandwidth memory (HBM) 140 may be bonded to the back-side redistribution layer structure 170 by the connection members 185, and thereby electrically connected thereto.

FIG. 11 is a cross-sectional view showing the step of molding the logic die 130, the high bandwidth memory (HBM) 140, and the substrate 150 with the molding material 160, on the back-side redistribution layer structure 170, subsequently to FIG. 6.

Referring to FIG. 11, on the back-side redistribution layer structure 170, the logic die 130, the high bandwidth memory (HBM) 140, and the substrate 150 may be covered with the molding material 160. In an embodiment, the process of molding with the molding material 160 may include a compression molding or transfer molding process. In an embodiment, the molding material 160 may include an epoxy molding compound (EMC).

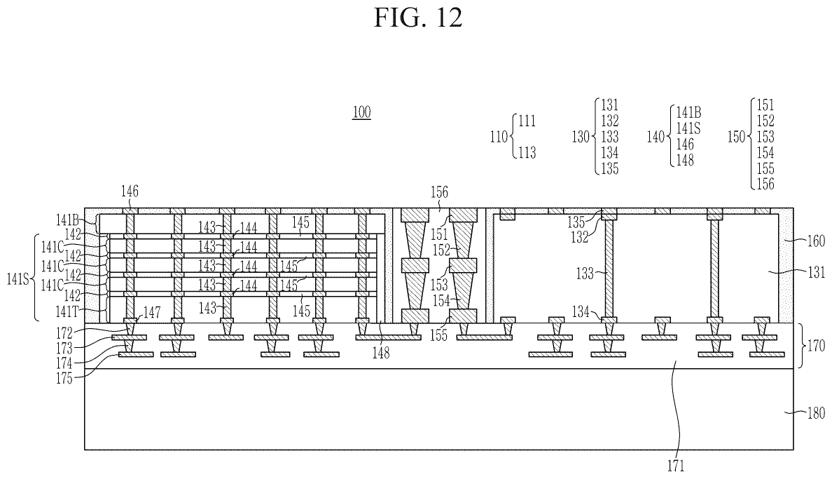

FIG. 12 is a cross-sectional view showing the step of planarizing the molding material 160.

Referring to FIG. 12, the planarization process may be performed in order to level an upper surface of the molding material 160. In an embodiment, the planarization process may include a chemical mechanical polishing (CMP). After performing the CMP process, an upper surface of the substrate 150, the first connection terminals 135 of the logic die 130, and the second connection terminals 146 of the high bandwidth memory (HBM) 140 may be exposed.

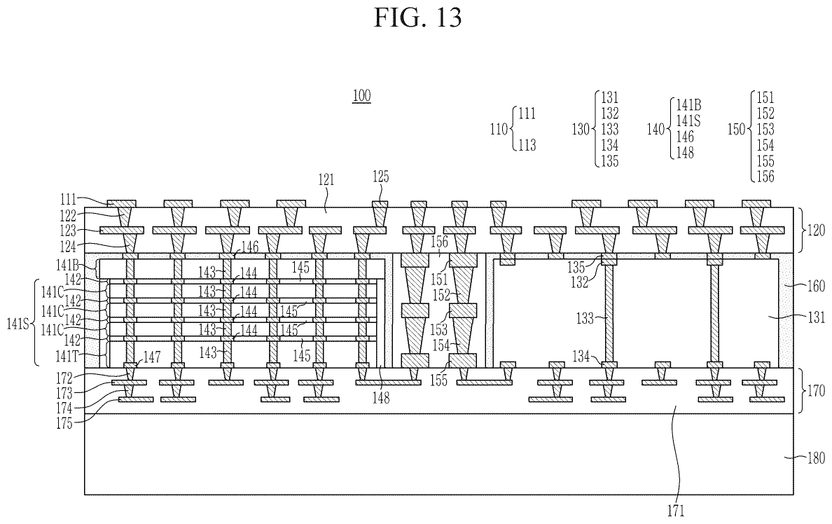

FIG. 13 is a cross-sectional view showing the step of forming the front-side redistribution layer structure 120 on the logic die 130, the high bandwidth memory (HBM) 140, the substrate 150, and the molding material 160.

Referring to FIG. 13, the front-side redistribution layer structure 120 may be formed on the logic die 130, the high bandwidth memory (HBM) 140, the substrate 150, and the molding material 160.

First, the first dielectric 121 may be formed on the logic die 130, the high bandwidth memory (HBM) 140, the substrate 150, and the molding material 160. In an embodiment, the first dielectric 121 may be formed of an organic dielectric material. In an embodiment, the first dielectric 121 may be formed by performing a spin coating process.

After forming the first dielectric 121, the first dielectric 121 may be selectively etched to form via holes, and the second redistribution vias 124 may be formed by filling a conducting material in the via holes. After forming the second redistribution vias 124, the first dielectric 121 may be additionally formed on the second redistribution vias 124 and the first dielectric 121, the additionally formed first dielectric 121 may be selectively etched to form openings, and the first redistribution lines 123 may be formed by filling a conducting material in the openings. After forming the first redistribution lines 123, the first dielectric 121 may be additionally formed on the first redistribution lines 123 and the first dielectric 121, and the additionally formed first dielectric 121 may be selectively etched to form via holes, and the first redistribution vias 122 may be formed by filling a conducting material in the via holes. After forming the first redistribution vias 122, a photoresist (not shown) may be additionally deposited on the first redistribution vias 122 and the first dielectric 121, the photoresist may be selectively exposed and developed to form a photoresist pattern including via holes, and the first connection pads 111 and second connection pads 125 may be formed by filling a conducting material in the via holes.

Based on the final semiconductor package 100, since the front-side redistribution layer structure 120 is manufactured upside down, a width of an uppermost portion of each of the first redistribution vias 122 in the final product may be smaller than the width of the lowermost portion, and a width of an uppermost portion of each of the second redistribution vias 124 may be smaller than the width of the lowermost portion.

In an embodiment, each the first redistribution vias 122, the first redistribution lines 123, the second redistribution vias 124, the first connection pads 111, and the second connection pads 125 may include at least one of copper, aluminum, tungsten, nickel, gold, tin, titanium, and an alloy thereof. In an embodiment, the first redistribution vias 122, the first redistribution lines 123, the second redistribution vias 124, the first connection pads 111, and the second connection pads 125 each may be formed by performing a sputtering process. In another embodiment, each of the first redistribution vias 122, the first redistribution lines 123, the second redistribution vias 124, the first connection pads 111, and the second connection pads 125 may be formed by performing an electroplating process after forming a seed metal layer.

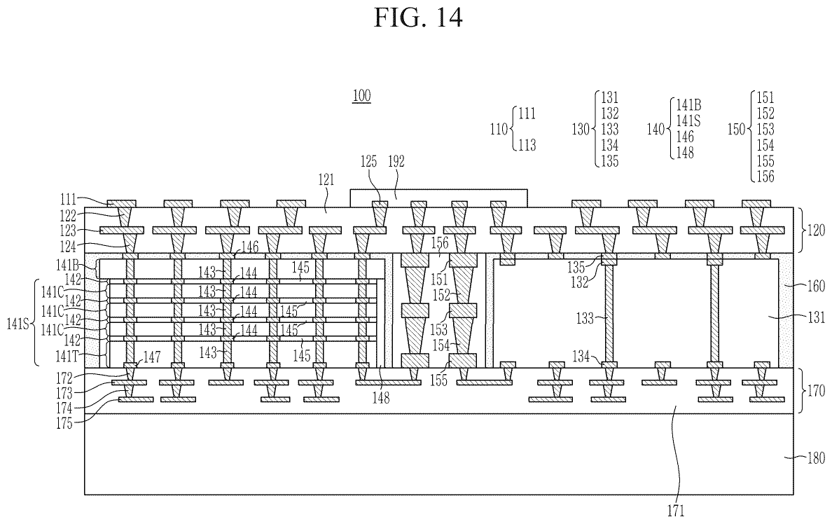

FIG. 14 is a cross-sectional view showing the step of attaching the insulation member 192 on the front-side redistribution layer structure 120 around the second connection pads 125.

Referring to FIG. 14, the insulation member 192 may be attached on the front-side redistribution layer structure 120 around the second connection pads 125. In an embodiment, the insulation member 192 may include a non-conductive film (NCF). The non-conductive film (NCF) may have adhesiveness and may be attached on the front-side redistribution layer structure 120 around the second connection pads 125. The non-conductive film (NCF) may have an uncured state, to be capable of deforming by an external force.

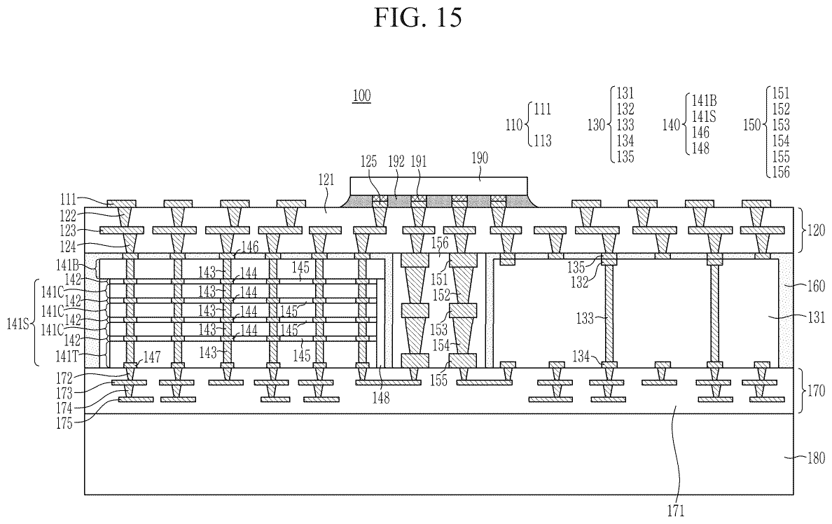

FIG. 15 is a cross-sectional view showing the step of bonding the power management integrated circuit (PMIC) die 190 to the second bonding pads 125.

Referring to FIG. 15, the power management integrated circuit (PMIC) die 190 may be bonded to the second connection pads 125 by using the connection members 191. Each of the connection members 191 provided in the power management integrated circuit (PMIC) die 190 may penetrate the non-conductive film (NCF) and be bonded to a corresponding second connection pad 125.

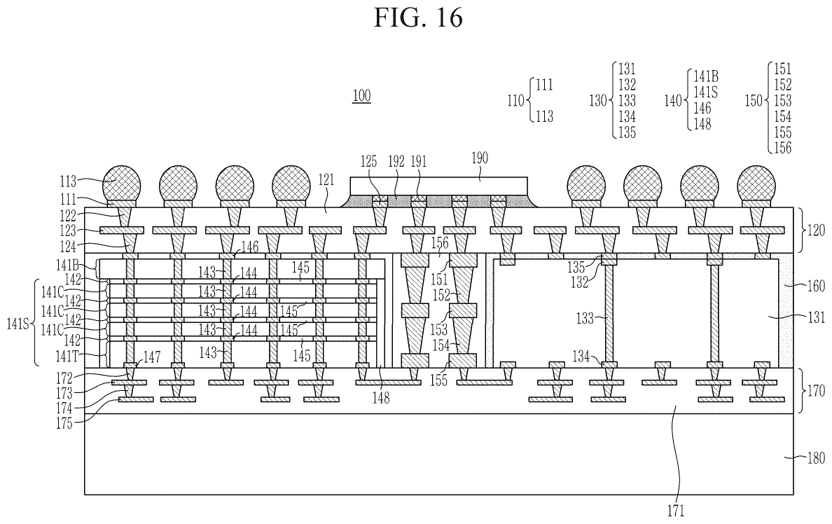

FIG. 16 is a cross-sectional view showing the step of forming the external connection members 113 on the front-side redistribution layer structure 120.

Referring to FIG. 16, the external connection members 113 on the front-side redistribution layer structure 120 may be formed. Each of the external connection members 113 may be formed on a corresponding first connection pad 111. In an embodiment, the external connection member 113 may include at least one of tin, silver, lead, nickel, copper or an alloy thereof.

Thereafter, the carrier 180 may not be removed and may serve as the heat dissipation structure.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the disclosure.

What is claimed is:

1. A semiconductor package, comprising:
a first redistribution layer;
a logic die on the first redistribution layer;
a high bandwidth memory on the first redistribution layer and next to the logic die;
a frame on the first redistribution layer, next to the logic die, and next to the high bandwidth memory;
a molding material covering the logic die, the high bandwidth memory, and the frame, on the first redistribution layer; and
a second redistribution layer on the molding material, wherein the second redistribution layer electrically connects the logic die to the high bandwidth memory.

2. The semiconductor package of claim 1, wherein the first redistribution layer electrically connects the logic die to the high bandwidth memory.

3. The semiconductor package of claim 1, wherein:
the high bandwidth memory comprises a buffer die and a plurality of memory dies stacked on the buffer die; and
an uppermost memory die among the plurality of memory dies is electrically connected to the second redistribution layer.

4. The semiconductor package of claim 3, wherein:
the uppermost memory die among the plurality of memory dies comprises a plurality of through-substrate vias; and
the plurality of through-substrate vias are electrically connected to the second redistribution layer.

5. The semiconductor package of claim 3, wherein the uppermost memory die among the plurality of memory dies is in contact with the second redistribution layer.

6. The semiconductor package of claim 1, wherein the logic die comprises a plurality of through-substrate vias.

7. The semiconductor package of claim 6, wherein the plurality of through-substrate vias electrically connect the second redistribution layer to the first redistribution layer.

8. The semiconductor package of claim 1, wherein the logic die is in contact with the second redistribution layer.

9. The semiconductor package of claim 1, wherein the first redistribution layer comprises:
an organic dielectric; and
a plurality of first circuit wirings within the organic dielectric.

10. The semiconductor package of claim 9, wherein the organic dielectric comprises a photo imageable dielectric (PID).

11. The semiconductor package of claim 1, wherein the second redistribution layer comprises:
an inorganic dielectric; and
a plurality of second circuit wirings within the inorganic dielectric.

12. The semiconductor package of claim 11, wherein the inorganic dielectric comprises at least one of silicon oxide, silicon nitride, silicon oxynitride, tetraethyl orthosilicate (TEOS) formation oxide, phosphosilicate glass (PSG), borophosphosilicate glass (BPSG), and a low-k dielectric material.

13. A semiconductor package, comprising:
a first redistribution layer comprising a first surface and a second surface opposite to the first surface;
a logic die on the first surface of the first redistribution layer;
a high bandwidth memory on the first surface of the first redistribution layer and next to the logic die;
a frame on the first surface of the first redistribution layer and between the logic die and the high bandwidth memory;
a molding material covering the logic die, the high bandwidth memory, and the frame, on the first surface of the first redistribution layer;
a second redistribution layer on the molding material, on the logic die, on the high bandwidth memory, and on the frame, wherein the second redistribution layer electrically connects the logic die to the high bandwidth memory;
a heat sink on the second redistribution layer; and
a power management integrated circuit (PMIC) die on the second surface of the first redistribution layer.

14. The semiconductor package of claim 13, wherein the frame comprises an embedded trace substrate (ETS).

15. The semiconductor package of claim 13, wherein the frame is configured to transfer electric power from the PMIC die to the logic die and to the high bandwidth memory through the second redistribution layer.

16. The semiconductor package of claim 13, wherein the heat sink comprises metal or silicon.

17. The semiconductor package of claim 13, further comprising a plurality of connection members on the second surface of the first redistribution layer,
wherein the PMIC die is at least partially surrounded by the plurality of connection members.

18. A manufacturing method of a semiconductor package, comprising:
forming a back-side redistribution layer on a carrier;
bonding a logic die, a high bandwidth memory, and a frame on the back-side redistribution layer, wherein the back-side redistribution layer electrically connects the logic die to the high bandwidth memory;
molding the logic die, the high bandwidth memory, and the frame with a molding material, on the back-side redistribution layer; and
forming a front-side redistribution layer on the molding material, the logic die, the high bandwidth memory, and the frame.

19. The manufacturing method of claim 18, wherein, in the bonding of the logic die, the high bandwidth memory, and the frame on the back-side redistribution layer, the logic die, the high bandwidth memory, and the frame are bonded on the back-side redistribution layer by a thermal compression process.

20. The manufacturing method of claim 18, wherein, after forming the front-side redistribution layer, the carrier is not removed to form the semiconductor package.
